(19) United States
(12) Patent Application Publication
(10) Pub. No.: US 2006/0138490 A1
(43) Pub. Date: Jun. 29, 2006

(54) CMOS image sensor and method for fabricating the same

(76) Inventor: Joon Hwang, Cheongju-city (KR)

Correspondence Address: Song K. Jung;MCKENNA LONG & ALDRIDGE LLP, 1900 K. Street, N.W., Washington, DC, 20006, US

(21) Appl. No.: 11/318,432

(22) Filed: Dec. 28, 2005

(30) Foreign Application Priority Data
Dec. 29, 2004 (KR) 2004-0114842

(51) Int. Cl. H01L 31/113

(52) U.S. Cl. 257/292

(57) ABSTRACT

A method for fabricating a CMOS image sensor includes forming a photodiode region, a gate electrode, an interlayer dielectric layer, a metal line, and a passivation layer on a semiconductor substrate having a pixel array region and a peripheral circuit region, forming a color filter layer having a plurality of filter elements for filtering colors on the passivation layer of the pixel array region, forming the light-shielding layer on the color filter layer, planarizing the light-shielding layer until surface of the color filter layer are exposed, and forming a microlens on the light-shielding layer.

### CROSS REFERENCE TO RELATED APPLICATION

This application claims the benefit of Korean Patent Application No. 10-2004-0114842, filed on Dec. 29, 2004, which is hereby incorporated by reference as if fully set forth herein.

### BACKGROUND OF THE INVENTION

1. Field of the Invention

The present invention relates to a CMOS image sensor, and more particularly, to a CMOS image sensor having a light-shielding layer and a method for fabricating the same in which the light-shielding layer is formed on a region where respective color filters of a pixel region join with each other and a peripheral circuit region to improve color reproduction.

2. Discussion of the Related Art

Generally, an image sensor is a semiconductor device that converts optical images to electrical signals. The image sensor is classified as a charge coupled device (CCD) and a complementary MOS (CMOS) image sensor. In a CCD, a plurality of metal-oxide-metal (MOS) capacitors are arranged close to one another to transfer and store electric charge carriers. In a CMOS image sensor, a plurality of MOS transistors corresponding to the number of pixels are fabricated by CMOS technology using a control circuit and a signal processing circuit as peripheral circuits. A switching system for detecting outputs step-by-step using the MOS transistors is adopted.

The CMOS image sensor includes signal processing chips having photodiodes. Since an amplifier, an analog/digital (A/D) converter, an inner voltage generator, a timing generator, a digital logic, and other components can be integrated on each of the chips, the CMOS image sensor can have a higher degree of integration. Moreover, the CMOS image sensor can have advantageous power consumption and cost reductions as well. The mass production of the CMOS image sensor is enabled through an etch process of silicon wafer cheaper than that of the CCD because the CCD is fabricated through a special process.

FIG. 1 illustrates a color filter array of a pixel region in a conventional CMOS image sensor.

As shown in FIG. 1, a green color filter 10, a blue color filter 11, and a red color filter 12 are repeatedly arranged. The color filters are formed using a negative photoresist. A pattern void 13 is generated in a region where the respective color filters join with each other. For example, pattern void 13 is generated in a region where two green color filters 10, the blue color filter 11 and the red color filter 12 join with one another. The pattern void 13 generates a noise signal because incident light passes into the void without passing through the color filters.

FIG. 2 is a sectional view illustrating a conventional CMOS image sensor.

As shown in FIG. 2, an element layer 17, which can include a photodiode region, a gate electrode, an interlayer dielectric layer, and a metal line, is formed on a semiconductor substrate 16 having a pixel array region 14 and a peripheral circuit region 15. A passivation layer 18 is deposited on the element layer 17. A blue color filter pattern 11, a red color filter pattern 12, and a green color filter pattern 10 are sequentially deposited on the passivation layer 18 of the pixel array region 14. An overcoating layer 19 having a transmittance is formed on the blue color filter pattern 11, the red color filter pattern 12, and the green color filter pattern 10. The overcoating layer 19 of the peripheral circuit region 15 is then removed. A microlens pattern 20 is formed on the overcoating layer 19.

In the CMOS image sensor manufactured discussed above, red, green and blue color are selectively filtered by the color filters in the pixel array region so that light energy is transferred to the photodiode region. However, light energy transferred to the peripheral circuit region is not filtered by color filters, whereby unnecessary electron-hole pairs are generated in an analog circuit region, and thusly, a large amount of noise is generated. Also, in the pixel array region, light is guided to the photodiode without passing through the color filters due to the void in the region where the respective color filters join with each other, thereby generating noise. This causes color reproduction to deteriorate.

### SUMMARY OF THE INVENTION

Accordingly, the present invention is directed to a light-shielding layer of a CMOS image sensor and a method for forming the same, which substantially obviate one or more problems that may be due to limitations and disadvantages of the related art.

The present invention can provide a CMOS image sensor and a method for fabricating the same in which the light-shielding layer is formed on both a region where respective color filters of a pixel region join with each another and a peripheral circuit region in order to avoid unnecessary incident light and reduce noise.

Additional advantages and features of the invention will be set forth in part in the description which follows and in part will become apparent to those having ordinary skill in the art upon examination of the following. These and other advantages of the invention may be realized and attained by the structure particularly pointed out in the written description and claims hereof as well as the appended drawings.

A CMOS image sensor according to one aspect of the present invention includes a semiconductor substrate provided with a photodiode region, a gate electrode, an interlayer dielectric layer and a metal line, and defined by a pixel array region and a peripheral circuit region, a color filter layer formed on the semiconductor substrate, the color filter having a plurality of filter elements for filtering colors, the light-shielding layer formed on a region where the respective filter elements join with each other, and a microlens formed on the light-shielding layer of the pixel region.

A region where four adjacent filter elements among the filter elements join with one another can be filled with the light-shielding layer.

The light-shielding layer can be formed on the peripheral circuit region.

The light-shielding layer can be formed of a black material.

In another aspect of the present invention, a method for fabricating a CMOS image sensor can include forming a photodiode region, a gate electrode, an interlayer dielectric layer, a metal line, and a passivation layer on a semiconductor substrate having a pixel array region and a peripheral circuit region; forming a color filter layer having a plurality of filter elements for filtering colors on the passivation layer of the pixel array region; forming the light-shielding layer on the color filter layer; planarizing the light-shielding layer until surface of the color filter layer are exposed; and forming a microlens on the light-shielding layer.

A region where four adjacent filter elements among the filter elements join with one another can be filled with the light-shielding layer.

The light-shielding layer can be formed of a black material.

In another aspect of the present invention, a method for fabricating a CMOS image sensor can include forming a photodiode region, a gate electrode, an interlayer dielectric layer, a metal line, and a passivation layer on a semiconductor substrate having a pixel array region and a peripheral circuit region; forming a color filter layer having a plurality of filter elements for filtering colors on the passivation layer of the pixel array region; forming the light-shielding layer on the passsivation layer including the color filter layer; planarizing the light-shielding layer until surface of the color filter layer are exposed; and forming a microlens on the light-shielding layer.

A region where four adjacent filter elements among the filter elements join with one another can be filled with the light-shielding layer, and the light-shielding layer remains in the peripheral circuit region.

The light-shielding layer can be formed of a black material.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention illustrate embodiments of the invention and together with the description serve to explain the principle of the invention. In the drawings:

FIG. 1 illustrates a color filter array of a pixel region in a conventional CMOS image sensor;

FIG. 2 is a sectional view illustrating a conventional CMOS image sensor;

FIG. 3-5 are sectional views illustrating a method of fabricating a CMOS image sensor according to one exemplary embodiment of the present invention; and

FIG. 6 illustrates a color filter array of a pixel region in a CMOS image sensor according to the present invention.

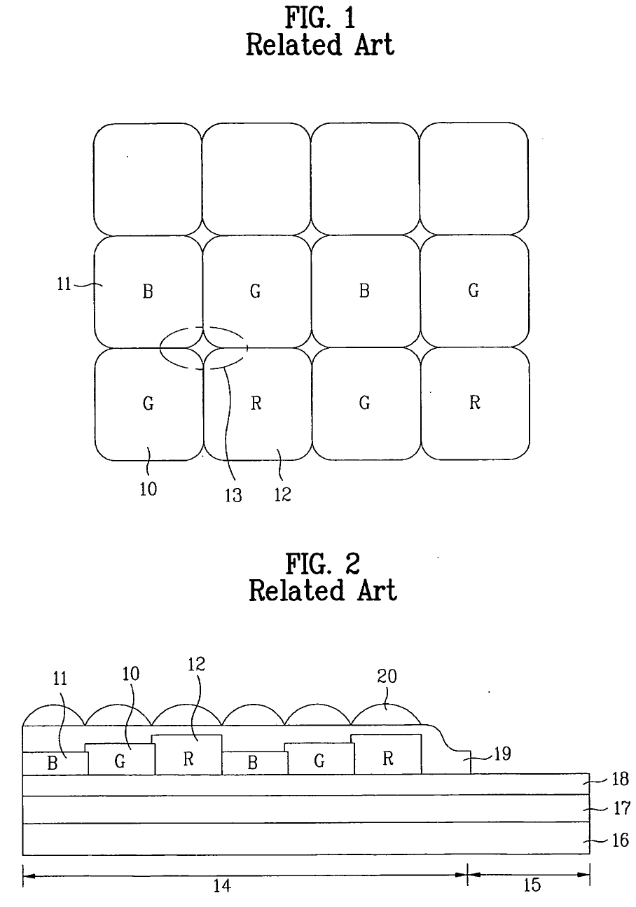

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

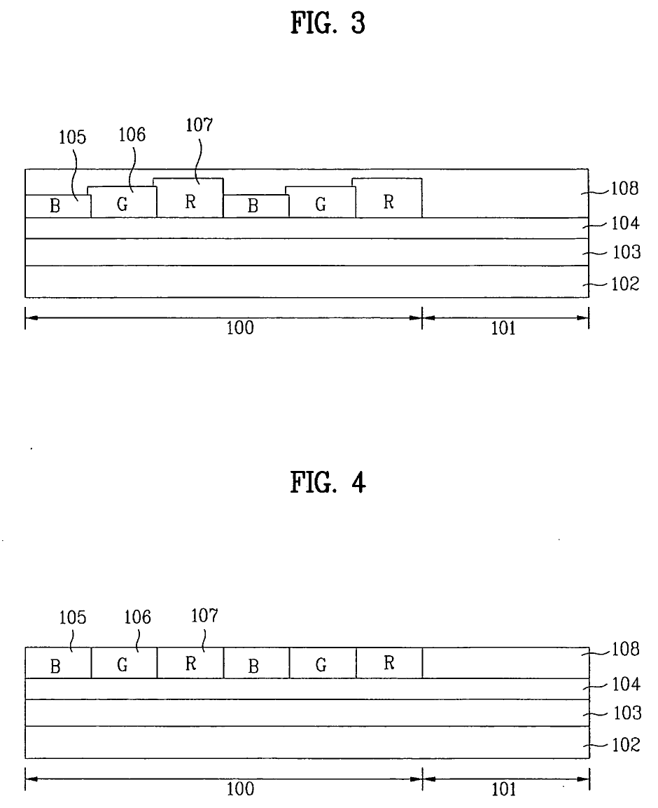

FIG. 3 to FIG. 5 are sectional views illustrating method of fabricating a CMOS image sensor according to one exemplary embodiment of the present invention.

As shown in FIG. 3, an element layer 103, including elements such as a photodiode region, a gate electrode, an interlayer dielectric layer, and a metal line, is formed on a semiconductor substrate 102 having a pixel array region 100 and a peripheral circuit region 101. A passivation layer 104 is deposited on the element layer 103. A blue color filter 105, a green color filter 106, and a red color filter 107 are sequentially deposited on the passivation layer 104 of the pixel array region 100.

A light-shielding layer 108 is formed on the blue color filter 105, the green color filter 106, and the red color filter 107 of the pixel array region 100 and the peripheral circuit region 101. The light-shielding layer can be formed of a black material.

As shown in FIG. 4, the light-shielding layer 108 is etched by a chemical mechanical polishing (CMP) process or an etch back process until the surfaces of the blue color filter 105, the green color filter 106, and the red color filter 107 are exposed.

Referring to FIG. 4, after the light-shielding layer 108 of FIG. 3 is etched, a void 109 (as shown in FIG. 6) in a region where four adjacent color filters join with one another in the pixel array region 100 is filled with the light-shielding layer 108. Incident light on the photodiode region will only pass through the color filters, which will reduce or eliminate noise.

As show in FIG. 3, because light-shielding layer 180 is formed on the pixel array region and the peripheral circuit region, the light-shielding layer 108 shields incident light on the peripheral circuit region 101.

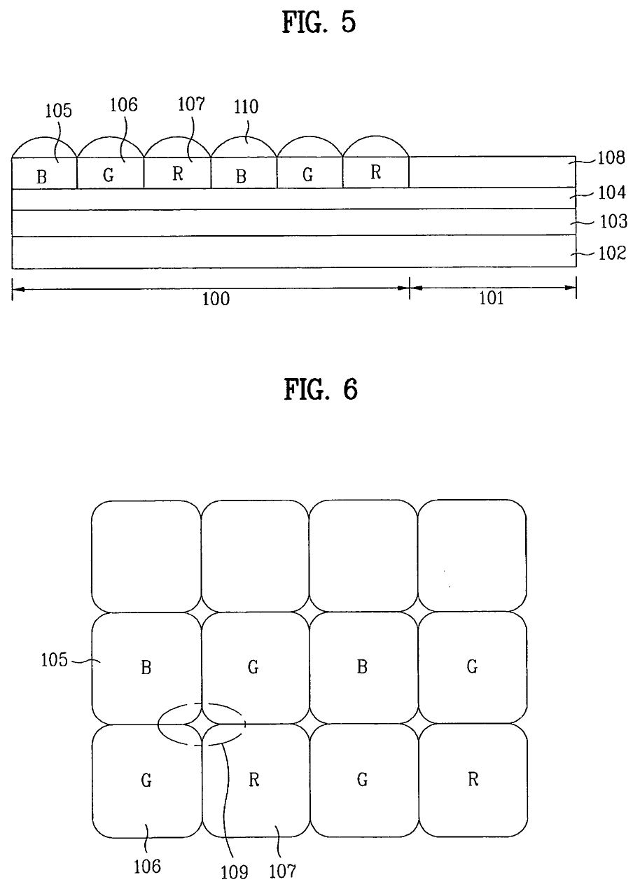

Finally, a microlens 110 is formed directly on the light-shielding layer 108 as shown in FIG. 5, unlike the conventional device in which the microlens 110 is formed on an overcoating layer.

In the embodiments above, the light-shielding layer is formed on the passivation layer in both the pixel array region and the peripheral circuit region. Alternatively, the light-shielding layer can be formed on the pixel array region but not on the peripheral circuit region. In particular, the light-shielding layer can be formed only on the color filters in the pixel array region.

Since the void in the region where four color filters join with one another in the pixel array region is filled with the light-shielding layer and the light-shielding layer is formed on the peripheral circuit region, the present invention may reduce noise caused by unnecessary incident light and improve color reproduction.

In addition, since light-shielding layer is planarized so as not to need to form the overcoating layer before the microlens is formed, the present invention may simplify the process steps.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A CMOS image sensor comprising:
a semiconductor substrate provided with a photodiode region, a gate electrode, an interlayer dielectric layer, and a metal line, wherein the semiconductor substrate has a pixel array region and a peripheral circuit region;
a color filter layer formed on the semiconductor substrate, the color filter layer having a plurality of filter elements for filtering colors and being formed on the semiconductor substrate at constant intervals;
a light-shielding layer formed on a region where the respective filter elements join with each other; and
at least one microlens formed on the light-shielding layer of the pixel region.

2. The CMOS image sensor as claimed in claim 1, wherein the region where four adjacent filter elements join with one another is filled with the light-shielding layer.

3. The CMOS image sensor as claimed in claim 1, wherein the light-shielding layer formed on the peripheral circuit region.

4. The CMOS image sensor as claimed in claim 1, wherein the light-shielding layer is formed by a black material.

5. A method for forming a light-shielding layer of a CMOS image sensor comprising:
forming a photodiode region, a gate electrode, an interlayer dielectric layer, a metal line and a passivation layer on a semiconductor substrate having a pixel array region and a peripheral circuit region;
forming a color filter layer having a plurality of filter elements for filtering colors on the passivation layer of the pixel array region;
forming the light-shielding layer on the color filter layer;
planarizing the light-shielding layer until at least one surface of the color filter layer is exposed; and
forming at least one microlens on the light-shielding layer.

6. The method as claimed in claim 5, wherein a region where four adjacent filter elements join with one another is filled with the light-shielding layer.

7. The method as claimed in claim 5, wherein the light-shielding layer is formed with a black material.

8. A method for forming a light-shielding layer of a CMOS image sensor comprising:
forming a photodiode region, a gate electrode, an interlayer dielectric layer, a metal line and a passivation layer on a semiconductor substrate having a pixel array region and a peripheral circuit region;
forming a color filter layer having a plurality of filter elements for filtering colors on the passivation layer of the pixel array region;
forming the light-shielding layer on the passivation layer, including the color filter layer;
planarizing the light-shielding layer until at least one surface of the color filter layer is exposed; and
forming at least one microlens on the light-shielding layer.

9. The method as claimed in claim 8, wherein a region where four adjacent filter elements join with one another is filled with the light-shielding layer, and the light-shielding layer remains in the peripheral circuit region.

10. The method as claimed in claim 8, wherein the light-shielding layer is formed with a black material.
